(19) United States
(12) Patent Application Publication
(10) Pub. No.: US 2024/0387781 A1
(43) Pub. Date: Nov. 21, 2024

(54) MICRO LED STRUCTURE AND MICRO DISPLAY PANEL

(71) Applicant: JADE BIRD DISPLAY (SHANGHAI) LIMITED, SHANGHAI (CN)

(72) Inventors: Yuankun ZHU, Shanghai (CN); Anle FANG, Shanghai (CN); Deshuai LIU, Shanghai (CN)

(21) Appl. No.: 18/788,095

(22) Filed: Jul. 29, 2024

Related U.S. Application Data
(63) Continuation of application No. PCT/CN2022/075286, filed on Jan. 31, 2022.

(51) Int. Cl. H01L 33/46; H01L 27/15

(52) U.S. Cl. CPC H01L 33/46; H01L 27/156

(57) ABSTRACT

A micro light emitting diode (LED) structure includes a mesa structure. The mesa structure further includes a first semiconductor layer, a light emitting layer formed on the first semiconductor layer, a second semiconductor layer formed on the light emitting layer, a sidewall protective layer formed on the sidewalls of the mesa structures, and a sidewall reflective layer formed on the surface of the sidewall protective layer. A top surface area of the second semiconductor layer is greater than each of: a bottom surface area of the first semiconductor layer, a top surface area of the first semiconductor layer, and a bottom surface area of the second semiconductor layer.

### CROSS-REFERENCE TO RELATED APPLICATIONS

This patent application is a continuation of Patent Cooperation Treaty Application No. PCT/CN2022/075286, filed Jan. 31, 2022, which is incorporated by reference herein in its entirety.

### TECHNOLOGY FIELD

The disclosure generally relates to a light emitting diode technology field and, more particularly, to a micro light emitting diode (LED) structure and a micro display panel comprising the micro LED structure.

### BACKGROUND

Inorganic micro light emitting diodes (also referred to as “micro LEDs” or “μ-LEDs”) are more and more important because of their use in various applications including, for example, self-emissive micro-displays, visible light communications, and opto-genetics. The μ-LEDs have greater output performance than conventional LEDs due to better strain relaxation, improved light extraction efficiency, uniform current spreading, etc. Compared with the conventional LEDs, the μ-LEDs feature in improved thermal effects, improved operation at higher current density, better response rate, greater operating temperature range, higher resolution, higher color gamut, higher contrast, lower power consumption, etc.

The μ-LEDs include III-V group epitaxial layers to form multiple mesas. In some μ-LED designs, space needs to be formed between adjacent μ-LEDs to avoid carriers in the epitaxial layers spreading from one mesa to an adjacent mesa. The space formed between the adjacent micro LEDs may reduce the active light emitting area and decrease the light extraction efficiency. Eliminating the space may increase the active light emitting area, but it would cause the carriers in the epitaxial layers to spread laterally across adjacent mesas and thus reduce the light emitting efficiency. Furthermore, without the space between the adjacent mesas, crosstalk will be produced between the adjacent μ-LEDs, which would cause the μ-LEDs to be less reliable or accurate.

Additionally, in some μ-LEDs structures, small LED pixels with high current density will more likely experience red-shift, lower maximum efficiency, and inhomogeneous emission, which are usually caused by degraded electrical injection during fabrication. Moreover, the peak external quantum efficiencies (EQEs) and the internal quantum efficiency (IQE) of the micro LEDs can be greatly decreased with the decreasing chip size. The decreased EQE and IQE is caused by nonradiative recombination at the sidewalls of the quantum well that are not properly etched. The decreased IQE is caused by poor current injection and electron leakage current of μ-LEDs. Improving the EQE and IQE requires optimization of the quantum well sidewall area to reduce the current density.

### BRIEF SUMMARY OF THE DISCLOSURE

In accordance with the present disclosure, there is provided a micro LED structure. The structure includes a mesa structure. The mesa structure further includes a first semiconductor layer, a light emitting layer formed on the first semiconductor layer, a second semiconductor layer formed on the light emitting layer, a sidewall protective layer formed on the sidewalls of the mesa structures, and a sidewall reflective layer formed on the surface of the sidewall protective layer. A top surface area of the second semiconductor layer is greater than each of a bottom surface area of the first semiconductor layer, a top surface area of the first semiconductor layer, and a bottom surface area of the second semiconductor layer.

Also in accordance with the present disclosure, there is provided a micro display panel. The micro display panel includes a micro LED array. The micro LED array includes a first micro LED structure and an integrated circuit (IC) back plane formed under the first micro LED structure. The first micro LED structure is electrically coupled to the IC back plane.

### BRIEF DESCRIPTION OF THE DRAWINGS

FIG. 1 is a schematic cross-sectional view of a micro LED structure, according to an exemplary embodiment of the present disclosure; and

FIG. 2 is a schematic cross-sectional view of at least a portion of an exemplary micro display panel, according to an exemplary embodiment of the present disclosure.

### DETAILED DESCRIPTION OF THE EMBODIMENTS

Hereinafter, embodiments consistent with the disclosure will be described with reference to the drawings. Wherever possible, the same reference numbers will be used throughout the drawings to refer to the same or like parts.

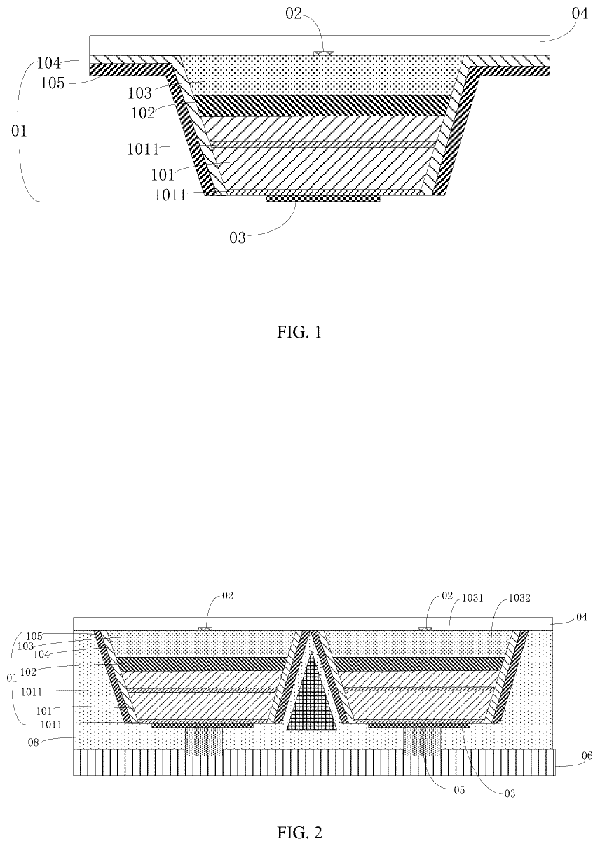

As discussed above, the state-of-art micro LEDs may experience problems like red-shift, low maximum efficiency, inhomogeneous emission, etc. To resolve these problems, a micro LED structure is provided in embodiments of the present invention. In some embodiments consistent with FIG. 1, a micro LED structure includes a mesa structure 01, a top contact 02, a bottom contact 03, a top conductive layer 04, a sidewall protective layer 104, and a sidewall reflective layer 105. The mesa structure 01 further includes a first type semiconductor layer 101, a light emitting layer 102, and a second type semiconductor layer 103. The light emitting layer 102 is formed on the top of the first type semiconductor layer 101. The second type semiconductor layer 103 is located on the top of the light emitting layer 102. In some embodiments, the first type and the second type refer to different conductive types. For example, the first type is P type, while the second type is N type. In another example, the first type is N type, while the second type is P type.

Still referring to FIG. 1, the sidewall protective layer 104 is formed on the sidewalls of the mesa structures 01 and the sidewall reflective layer 105 is formed on the surface of the sidewall protective layer 104. In some further embodiments, the sidewall protective layer 104 includes the same materials as the material of the first semiconductor layer 101 or the second semiconductor layer 103. The sidewall protective layer 104 includes material without conductive property. In some embodiments, the sidewall protective layer 104 includes InP or GaAs. The sidewall protective layer 104 is bonded with the sidewall of the mesa structure 01 via atomic bonds. In some embodiments, the sidewall reflective layer 104 includes gold and silver. In some embodiment, the sidewall reflective layer 105 includes a dielectric material combined with gold and silver.

Still referring to FIG. 1, the top surface area of the second semiconductor layer 103 is made greater than the top surface area of the first semiconductor layer 101. In some embodiments, the top surface area of the second semiconductor layer 103 is made greater than the bottom surface area of the second semiconductor layer 103. The top surface area of the first semiconductor layer 101 is made greater than the bottom surface area of the first semiconductor layer 101. In some embodiments, the sidewalls of the first semiconductor layer 101, the light emitting layer 102, and the second semiconductor layer 103 are in a same plane in the embodiment so that the sidewalls are flat. In some embodiments, the light emitting layer 102 and the second semiconductor layer 103 are not in a same plane and the sidewalls are not flat. In some embodiments, the diameter of the second semiconductor layer 103 is less than the diameter of the light emitting layer 102. In some embodiments, the diameter of the first semiconductor layer 101 is less than the diameter of the light emitting layer 102. In some embodiments, the material of the first type semiconductor layer 101 includes at least one of the p-GaAs, p-GaP, p-AlInP, p-GaN, p-InGaN, p-AlGaN, etc. The material of the second type semiconductor layer 103 includes at least one of the n-GaAs, n-AlInP, n-GaInP, n-AlGaAs, n-AlGaInP, n-InGaN, n-AlGaN, etc. The light emitting layer 102 is formed by a quantum well layer. The material of the quantum well layer includes at least one of the GaAs, InGaN, AlGaN, AllnP, GalnP, AlGaInP, etc. In some further embodiments, the thickness of the first type semiconductor layer 101 is greater than the thickness of the second type semiconductor layer 103, and the thickness of the light emitting layer 102 is less than the thickness of the first type semiconductor layer 101. In some embodiments, the thickness of the first type semiconductor layer 101 ranges from 700 nm to 2 μm and the thickness of the second type semiconductor layer 103 ranges from 100 nm to 200 nm. In some embodiments, the thickness of the quantum well layer is less than or equal to 30 nm. In some embodiments, the quantum well layer includes not more than three pairs of quantum wells.

In some embodiments, the first type semiconductor layer 101 includes one or more reflective mirrors 1011. In some embodiments, the reflective mirror 1011 is formed at the bottom surface of the first type semiconductor layer 101. In some embodiments, the reflective mirror 1011 is formed inside of the first type semiconductor layer 101. In some embodiments, the material of the reflective mirror 1011 is a mixture of dielectric material and metal material. In some further embodiments, the dielectric material includes SiO₂ or SiNx, in which “x” is a positive integer. In some embodiments, the metal material includes Au or Ag. In some embodiments, multiple reflective mirrors 1011 are horizontally formed in the first type semiconductor layer 1011 one by one in different horizontal levels, dividing the first type semiconductor layer 101 into multiple layers. In some embodiments, the top contact 02 is formed at the top surface of the second type semiconductor layer 103. The conductive type of the top contact 02 is the same as the conductive type of the second type semiconductor layer 103. For example, if the second type is N type, the top contact 02 is an N type contact; or if the second type is P type, the top contact 02 is a P type contact. In some embodiments, the top contact 02 is made by metal or metal alloy including at least one of AuGe, AuGeNi, etc. The top contact 02 is used for forming ohmic contact between the top conductive layer 04 and the second type semiconductor layer 103, optimizing the electrical property of the micro LEDs. In some embodiments, the diameter of the top contact 02 ranges from 20 nm to 50 nm and the thickness of the top contact 02 ranges from 10 nm to 20 nm.

Still referring to FIG. 1, in some embodiments, the micro LED structure further includes a top conductor layer 04 covering the top surface of the second type semiconductor layer 103 and the top contact 02. The top conductive layer 04 is transparent and electrically conductive. In some embodiment, the top conductive layer 04 includes at least one of indium tin oxide (ITO) and fluorine-doped tin oxide (FTO).

In some embodiments, the bottom contact 03 is formed at the bottom surface of the first type semiconductor layer 101. The conductive type of the bottom contact 03 is the same as the conductive type of the first type semiconductor layer 101. For example, if the first type semiconductor layer 101 is P type, the bottom contact 03 is also P type. Similarly, if the first type semiconductor layer 101 is N type, the bottom contact 03 is also N type. In some embodiments, the light emits from the top surface of the mesa structure 01. To this end, the diameter of the bottom contact 03 is made greater than the diameter of the top contact 02, and the diameter of the top contact 02 is made as small as possible such that the top contact 02 is like a dot on the top surface of the second type semiconductor layer 103. In some embodiments, the diameter of the bottom contact 03 is made equal to or smaller than the diameter of the top contact 02. In some embodiments, the bottom contact 03 is configured to connect to a bottom electrode such as a contact pad in an IC back plane. In some embodiments, the diameter of the bottom contact 03 ranges from 20 nm to 1 μm. In some embodiments, the diameter of the bottom contact 03 ranges from 800 nm to 1 μm. In some embodiments, the center of the bottom contact 03 is aligned with the center of the top contact 02 along an axis perpendicular to the upper surface of the first type semiconductor region. In some embodiments, the center of the bottom contact 03, the center of the top contact 02, and the center of the first type semiconductor region are all aligned along an axis perpendicular to the upper surface of the first type semiconductor region. In some embodiments, the material of the bottom contact 03 includes transparent conductive material. In some further embodiments, the material of the bottom contact 03 includes ITO or FTO. In some embodiments, the bottom contact 03 is not transparent and the material of the bottom contact is conductive metal. In some embodiments, the material of the bottom contact includes at least one of the following elements: Au, Zn, Be, Cr, Ni, Ti, Ag, and Pt.

In some embodiments consistent with FIG. 2, a micro display panel is provided. The micro display panel includes a micro LEDs array and an IC back plane 06 formed under the micro LED array. The micro LEDs array includes multiple aforementioned micro LED structures. The micro LED structures are electrically coupled or connected to the IC back plane 06. In some embodiments, the length of the whole micro LEDs array is no more than 5 cm. The length of the back plane 06 is greater than the length of the micro LED array. In some embodiments, the length of the back plane 06 is no greater than 6 cm. The area of the micro LED array is an active display area.

In some embodiments, the micro LED structure further includes a metal bonding structure. More particularly, the metal bonding structure includes a metal bonding layer or a connected hole. For example, as shown in FIG. 2, the metal bonding structure is a connected hole 05 and the connected hole 05 is filled with bonding metal. The top side of the connected hole 05 is connected to the bottom contact 03 and the bottom side of the connected hole 05 is connected to contact pads on the surface of the IC back plane 06. In some embodiments, the top conductive layer 04 in the micro display panel is made to cover the whole display panel.

Still referring to FIG. 2, the micro display panel further comprises a dielectric layer 08. The dielectric layer 08 is formed between adjacent mesa structures 01. The material of the dielectric layer 08 is not conductive so that the adjacent micro LEDs are electrically isolated. In some embodiments, the material of the dielectric layer includes at least one of the SiO₂, Si₃N₄, Al₂O₃, AlN, HfO₂, TiO₂, and ZrO₂. In some further embodiments, a reflective structure 07 is formed in the dielectric layer 08 between adjacent mesa structures 01 to avoid crosstalk. In some embodiments, the reflective structure 07 does not contact the mesa structures 01. In some embodiment, the top surface of the reflective structure 07 is aligned with the top surface of the mesa structure 01 and the bottom surface of the reflective structure 07 is aligned with the bottom surface of the mesa structure 01. The cross-sectional structure of the reflective structure 07 can be triangle, rectangle, trapezoid, or any other shapes of structures. In some embodiments, the sidewall reflective layer 105 is formed at the sidewalls of the mesa structure 01, the space between the adjacent mesa structures 01 can be formed as small as possible. In some embodiments, the bottom of the reflective structure 07 extends downward, lower than the bottom of the mesa structure 01.

Other embodiments of the disclosure will be apparent to those skilled in the art from consideration of the specification and practice of the invention disclosed herein. It is intended that the specification and examples be considered as exemplary only, with a true scope and spirit of the invention being indicated by the following claims.

1. A micro light emitting diode (LED) structure, comprising:
a mesa structure, comprising:
a first semiconductor layer;
a light emitting layer formed on the first semiconductor layer;
a second semiconductor layer formed on the light emitting layer;
a sidewall protective layer formed on a sidewall of the mesa structure; and,
a sidewall reflective layer formed on a surface of the sidewall protective layer;
wherein a top surface area of the second semiconductor layer is greater than each of: a bottom surface area of the first semiconductor layer, a top surface area of the first semiconductor layer, and a bottom surface area of the second semiconductor layer.

2. The micro LED structure according to claim 1, wherein the sidewall is flat.

3. The micro LED structure according to claim 1, wherein the sidewall is not flat.

4. The micro LED structure according to claim 1, wherein the sidewall protective layer comprises same material as the first semiconductor layer or the second semiconductor layer, and does not have conductive property.

5. The micro LED structure according to claim 4, wherein the material of the sidewall protective layer comprises InP or GaAs.

6. The micro LED structure according to claim 1, wherein the sidewall protective layer is bonded with the sidewall of the mesa structure via atomic bonds.

7. The micro LED structure according to claim 1, wherein material of the sidewall reflective layer comprises Au and Ag, or comprises dielectric material combined with Au and Ag.

8. The micro LED structure according to claim 1, further comprising a first reflective mirror formed on the bottom surface of the first semiconductor layer.

9. The micro LED structure according to claim 8, further comprising a second reflective mirror formed inside of the first semiconductor layer.

10. The micro LED structure according to claim 1, wherein a thickness of the first semiconductor layer is greater than a thickness of the second semiconductor layer.

11. The micro LED structure according to claim 10, wherein the thickness of the first semiconductor layer ranges from 700 nm to 2 μm and the thickness of the second semiconductor layer ranges from 100 nm to 200 nm.

12. The micro LED structure according to claim 11, wherein the thickness of a first concentration doped region ranges from 100 nm to 200 nm and the thickness of a second concentration doped region ranges from 100 nm to 150 nm.

13. The micro LED structure according to claim 1, wherein a thickness of the light emitting layer is less than a thickness of the first semiconductor layer.

14. The micro LED structure according to claim 1, wherein the light emitting layer is formed by a quantum well layer located between the first semiconductor layer and the second semiconductor layer.

15. The micro LED structure according to claim 14, wherein a thickness of the quantum well layer is less than or equal to 30 nm.

16. The micro LED structure according to claim 15, wherein the quantum well layer comprises three or less than three pairs of quantum wells.

17. The micro LED structure according to claim 1, further comprising a top contact formed on the top surface of the second semiconductor layer, and a top conductive layer formed on the second conductive layer and the top contact.

18. A micro display panel, comprising:
a micro light emitting diode (LED) array, comprising:
a first micro LED structure according to claim 1, the first micro LED structure comprising
a first mesa structure; and
an integrated circuit (IC) back plane formed under the first micro LED structure,
wherein the first micro LED structure is electrically coupled to the IC back plane.

19. The micro display panel according to claim 18, wherein the first micro LED structure further comprises,
a bottom contact,
a top contact,
a top conductive layer, and
a connected hole,
wherein a top side of the connected hole is connected with the bottom contact, and a bottom side of the connected hole is bonded with the IC back plane; and wherein the top conductive layer is formed on the display panel and is electrically coupled to the top contact.

20. The micro display panel according to claim 18, wherein the micro light emitting diode (LED) array further comprises:
a second micro LED structure according to claim 1, the second micro LED structure comprising a second mesa structure located adjacent to the first mesa structure; and
a dielectric layer, wherein the dielectric layer is not conductive and is formed between the first and second mesa structures.

21. The micro display panel according to claim 20, wherein material of the dielectric layer is at least one of SiO₂, Si₃N₄, Al₂O₃, AlN, HfO₂, TiO₂ and ZrO₂.

22. The micro display panel according to claim 21, wherein the sidewall reflective layers of the first and second mesa structures are connected at top surfaces of the first and second mesa structures.

23. The micro display panel according to claim 22, wherein top surfaces of the first and second mesa structures are connected, and the micro display panel further comprises a reflective structure in the dielectric layer between the first and second mesa structures, wherein a top surface of the reflective structure is under the connected top surfaces of the first and second mesa structures.

24. The micro display panel according to claim 23, wherein the reflective structure is triangle in shape.

25. The micro display panel according to claim 24, wherein the reflective structure comprises a first sidewall parallel to the sidewall reflective layer of the first mesa structure and a second side wall parallel to the sidewall reflective layer of the second mesa structure.
